(19) United States
(12) Patent Application Publication
(10) Pub. No.: US 2026/0095015 A1
(43) Pub. Date: Apr. 2, 2026

(54) LASER SYSTEM WITH INTEGRATED WAVELENGTH CONTROL

(71) Applicant: Lightmatter, Inc., Boston, MA (US)

(72) Inventors: Srinivasan Ashwyn Srinivasan, Toronto (CA); Jessie Rosenberg, Bedford, MA (US); Darius Bunandar, Boston, MA (US)

(73) Assignee: Lightmatter, Inc., Boston, MA (US)

(21) Appl. No.: 19/340,302

(22) Filed: Sep. 25, 2025

Related U.S. Application Data
(60) Provisional application No. 63/700,458, filed on Sep. 27, 2024.

(51) Int. Cl. H01S 3/13; G02B 6/293; H01S 3/00; H01S 3/067; H01S 3/23

(52) U.S. Cl. CPC H01S 3/1305; G02B 6/2938; H01S 3/0085; H01S 3/06745; H01S 3/2308; H01S 2301/02

(57) ABSTRACT

Described herein are compact, high-power tunable optical sources with precise wavelength control. The tunable optical sources developed by the inventors and described herein use laser arrays that are compatible with wavelength division multiplexing (WDM) schemes, making these sources particularly suitable for use in applications requiring high levels of data throughput. These sources use integrated wavemeters to measure the wavelength of optical emission. These wavemeters are formed monolithically on the same substrate hosting the laser array, resulting in a much smaller footprint than what is possible using conventional, external instrumentation. The wavemeters described herein use optical interferometers as part of a feedback control loop to ensure that the lasers emit light at the desired carrier wavelengths. A wavemeter can map the wavelength of emission of a laser to the wavelengths of emission of a calibrated optical source.

### CROSS-REFERENCE TO RELATED APPLICATIONS

This application claims the benefit under 35 U.S.C. § 119(e) of U.S. Provisional Application Ser. No. 63/700,458, filed on Sep. 27, 2024, under Attorney Docket No. L0858.70099US00 and entitled “LASER SYSTEM WITH INTEGRATED WAVELENGTH CONTROL,” which is hereby incorporated herein by reference in its entirety.

### BACKGROUND

Computer systems include random-access memories (RAM) for storing data and machine code. RAMs are typically volatile memories, such that the stored information is lost when power is removed. In conventional implementations, memories take the form of integrated circuits. Each integrated circuit includes several memory cells. To enable access to stored data and machine code, memories are placed in electrical communication with processors. Typically, these electrical communications are implemented as metal traces formed on the substrates on which the memories and the processors are disposed.

As integrated circuits have become increasingly complex, with multiple device dies packaged together to perform various functions, the performance of electrical interconnects has become a bottleneck, particularly for high-performance applications. Photonic integrated circuits (PICs) offer a promising solution to overcome the limitations of electrical interconnects. These PICs may include passive optical components (waveguides, multiplexers, etc.) and active optical components (modulators, diodes, etc.).

Lasers are often used to generate and supply light to PICs. For example, lasers provide coherent light that PICs can manipulate to encode information. Laser light can be injected into a PIC using edge coupling—through the facet of the PIC—or surface coupling—through the top or bottom surface of the PIC. Most commercial systems use external lasers or hybrid-integrated lasers. External lasers can provide high performance and temperature stabilization, but at the expense of alignment and packaging complexity. In some cases, lasers are kept in a separate laser box and connected via optical fibers to the PIC package. In hybrid integration (e.g., flip-chip bonding, die-to-wafer bonding, etc.), on the other hand, laser light is coupled into a PIC through very short interfaces within a package.

### BRIEF SUMMARY

In some aspects, the techniques described herein relate to an optical system, including: a substrate; a tunable laser array, formed on the substrate, including at least a first tunable laser; and an optical wavemeter, formed on the substrate, having: a first optical input coupled to the first tunable laser via a tap coupler; a second optical input coupled to a first input/output (I/O) coupler; a first optical output coupled to a first detector; and a second optical output coupled to a second detector.

In some aspects, the techniques described herein relate to an optical system, further including a calibrated optical source coupled to the second optical input of the optical wavemeter via the first I/O coupler.

In some aspects, the techniques described herein relate to an optical system, wherein the optical wavemeter includes an interferometer exhibiting an extinction ratio (ER) that is less than 15 dB.

In some aspects, the techniques described herein relate to an optical system, wherein the optical wavemeter further includes: first and second optical arms coupling the first and second optical inputs to the first and second optical outputs; and an optical coupler coupling the first and second optical arms to the first and second detectors.

In some aspects, the techniques described herein relate to an optical system, wherein the first and second optical arms have different optical lengths.

In some aspects, the techniques described herein relate to an optical system, wherein the optical coupler is an X/Y directional coupler, wherein X is between 55% and 95% and Y is between 5% and 45%.

In some aspects, the techniques described herein relate to an optical system, further including: an optical combiner, coupled to the tap coupler, configured to combine light received from the tunable lasers of the tunable laser array to a second I/O coupler.

In some aspects, the techniques described herein relate to an optical system, further including: an optical amplifier coupled to the optical combiner; and an etalon coupled to the second I/O coupler, wherein the etalon exhibits a periodic spectral response.

In some aspects, the techniques described herein relate to an optical system, wherein the etalon includes an optical resonator and a heater thermally coupled to the optical resonator.

In some aspects, the techniques described herein relate to an optical system, wherein the etalon exhibits a free spectral range that matches a spacing between adjacent carrier wavelengths of light emitted by the tunable laser array.

In some aspects, the techniques described herein relate to an optical system, further including a dither signal generator configured to drive the first tunable laser.

In some aspects, the techniques described herein relate to a tunable optical source, including: a substrate; a tunable laser array, formed on the substrate, including at least a first tunable laser; an optical wavemeter, formed on the substrate, having a first optical input coupled to the first tunable laser and a second optical input; and a controller configured to calibrate the first tunable laser using a first signal generated by the optical wavemeter upon reception of light through the second optical input.

In some aspects, the techniques described herein relate to a tunable optical source, wherein the optical wavemeter further includes a first optical output coupled to a first detector and a second optical output coupled to a second detector, wherein the first and second detectors are configured to generate the first signal upon reception of light through the second optical input.

In some aspects, the techniques described herein relate to a tunable optical source, wherein calibrating the first tunable laser using the first signal generated by the first and second detectors upon reception of light through the second optical input of the optical wavemeter includes: storing information indicative of the first signal generated by the first and second detectors in a memory; obtaining a second signal generated by the first and second detectors upon reception of light through the first optical input of the optical wavemeter; and mapping the second signal to the stored information indicative of the first signal.

In some aspects, the techniques described herein relate to a tunable optical source, wherein storing information indicative of the first signal generated by the first and second detectors in the memory includes: storing a first vector indicative of carrier wavelengths of the light received through the second optical input of the optical wavemeter; and storing a second vector indicative of magnitudes of the first signal for each carrier wavelength of the light received through the second optical input of the optical wavemeter.

In some aspects, the techniques described herein relate to a tunable optical source, further including an etalon coupled to the first tunable laser, wherein the controller is further configured to, upon calibrating the first tunable laser, vary a spectral response associated with the etalon to match a carrier wavelength of light emitted by the first tunable laser.

In some aspects, the techniques described herein relate to a tunable optical source, wherein varying the spectral response associated with the etalon includes controlling a heater to vary a temperature of the etalon.

In some aspects, the techniques described herein relate to a method of operating a tunable optical source, the method including: controlling a calibrated optical source to emit light; obtaining a first signal generated by first and second detectors upon reception of the emitted light by an optical wavemeter that is disposed on a substrate; and controlling a tunable laser, disposed on the substrate and coupled to the optical wavemeter, to emit light at a target carrier wavelength using the first signal generated by first and second detectors.

In some aspects, the techniques described herein relate to a method, wherein controlling the first tunable laser to emit light at the target carrier wavelength using the first signal includes: storing information indicative of the first signal generated by the first and second detectors in a memory; obtaining a second signal generated by the first and second detectors upon reception of light by the optical wavemeter; and mapping the second signal to the stored information indicative of the first signal.

In some aspects, the techniques described herein relate to a method, wherein storing information indicative of the first signal generated by the first and second detectors in the memory includes: storing a first vector indicative of carrier wavelengths of the light emitted by the calibrated optical source; and storing a second vector indicative of magnitudes of the first signal for each carrier wavelength of the light emitted by the calibrated optical source.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1A is a block diagram illustrating an example of a tunable optical source including an integrated wavemeter, in accordance with some embodiments.

FIG. 1B is a block diagram illustrating another example of a tunable optical source including an integrated wavemeter, in accordance with some embodiments.

FIG. 1C is a block diagram illustrating another example of a tunable optical source including an integrated wavemeter, in accordance with some embodiments.

FIG. 1D is a block diagram illustrating another example of a tunable optical source including an integrated wavemeter, in accordance with some embodiments.

FIG. 1E is a block diagram illustrating a portion of the tunable optical source of FIG. 1A in additional detail, in accordance with some embodiments.

FIG. 2A is a block diagram illustrating an example of a wavemeter implemented using a passive Mach-Zehnder interferometer (MZI), in accordance with some embodiments.

FIG. 2B is a block diagram illustrating an example of a wavemeter implemented using an active MZI, in accordance with some embodiments.

FIG. 2C is a block diagram illustrating an example of a wavemeter implemented using a 90-degree hybrid interferometer, in accordance with some embodiments.

FIG. 3A is a plot illustrating the response of the detectors of a wavemeter to reception of light from a calibrated source, in accordance with some embodiments.

FIG. 3B is a plot illustrating the combined response of a wavemeter to reception of light from a calibrated source, in accordance with some embodiments.

FIG. 3C is a plot illustrating the response of the detectors of a wavemeter to reception of light from a tunable laser, in accordance with some embodiments.

FIG. 3D is a plot illustrating the combined response of a wavemeter to reception of light from a tunable laser, in accordance with some embodiments.

FIG. 4A is a block diagram illustrating an example of an etalon, in accordance with some embodiments.

FIG. 4B is a block diagram illustrating another example of an etalon, in accordance with some embodiments.

### DETAILED DESCRIPTION

Described herein are compact, high-power tunable optical sources with precise wavelength control. The tunable optical sources developed by the inventors and described herein use laser arrays that are compatible with wavelength division multiplexing (WDM) schemes, making these sources particularly suitable for use in applications requiring high levels of data throughput, including in long-haul fiber optics links, data center and graphical processing unit (GPU) interconnectivity, accelerators and quantum computers. WDM is a technique in which multiple optical signals, each at a distinct carrier wavelength, are transmitted simultaneously over a single optical medium (e.g., a fiber). By combining wavelength carriers, WDM enables a significant increase in data throughput without the need for additional fibers.

Some embodiments of the tunable optical sources described herein use integrated wavemeters to calibrate the wavelength of optical emission. These wavemeters are formed monolithically on the same substrate hosting the laser array, resulting in a much smaller footprint than what is possible using conventional, external instrumentation. The wavemeters according to some embodiments use optical interferometers as part of a feedback control loop to ensure that the lasers emit light at the desired carrier wavelength. In some embodiments, calibration of a laser may involve mapping the wavelength of emission of the laser to the response of a wavemeter to light emitted by a calibrated optical source. This optical source is said to be “calibrated” in that its wavelength of emission is known. Several types of external lasers can be used to implement a calibrated optical source, including lasers commonly used in long-haul fiber optics links.

Some of the sources described herein can supply relatively high levels of output power per carrier wavelength, for example on the order of hundreds of milliwatts or even watts per wavelength. To enhance the output power, some embodiments employ integrated semiconductor optical amplifiers (SOA), devices that can boost the power of an optical carrier via stimulated emission. Optical gain in SOAs originates from the same mechanism as in a laser, namely, population inversion in the active medium. Unlike a laser cavity, however, an SOA has anti-reflection (AR)-coated facets so that feedback is suppressed, preventing it from lasing. The inventors have recognized and appreciated that use of SOAs presents a challenge; SOAs are noisy. Even without input light, carriers spontaneously recombine, emitting photons randomly. These photons also get amplified by the gain medium, creating amplified spontaneous emission (ASE) and resulting in a degradation of the signal-to-noise ratio. ASE manifests as a broadband noise background across the SOA's gain bandwidth.

To mitigate the negative effects of ASE, some embodiments employ etalons. Etalons are optical devices that exhibit periodic spectral response, typically in the form of equally spaced, narrow passbands. Light having wavelengths within a passband is transmitted through the etalon; light having wavelengths outside the passbands is suppressed. Thus, an etalon can suppress noise due to ASE arising outside the bands of interest for WDM communication. In addition to reducing noise caused by ASE, etalons of the types described herein ensure that the carrier wavelengths emitted by the lasers are aligned with the desired WDM grid. Light is transmitted through the etalon only to the degree that its spectral content matches the spectral grid defined by the etalon. Thus, etalons have a dual purpose. They reduce noise while ensuring compliance with the desired WDM grid.

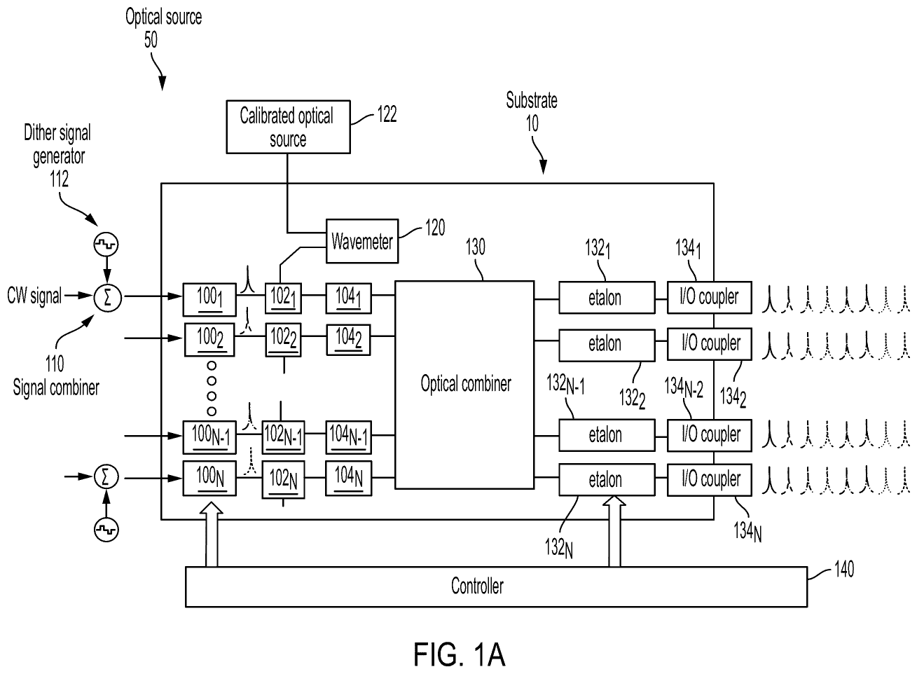

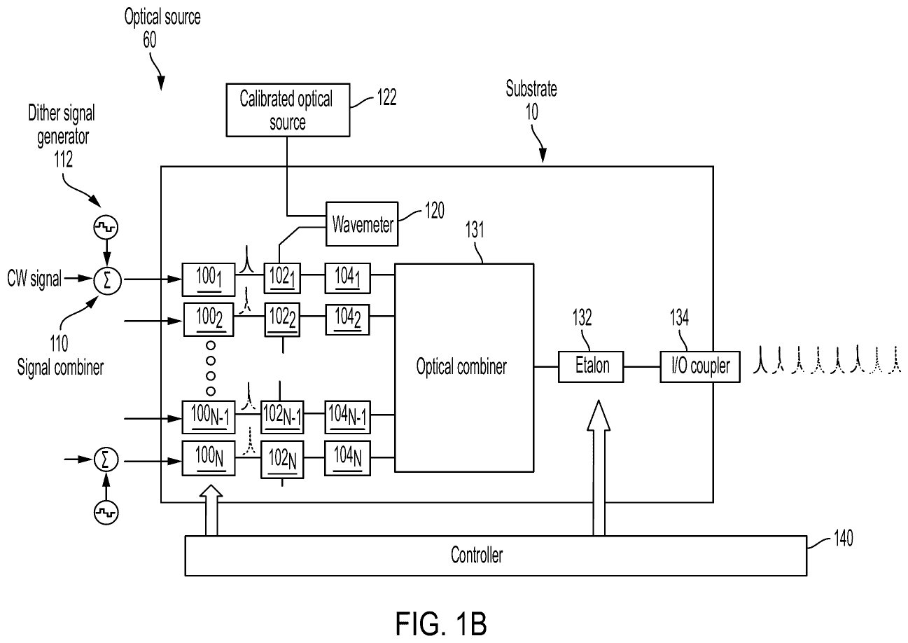

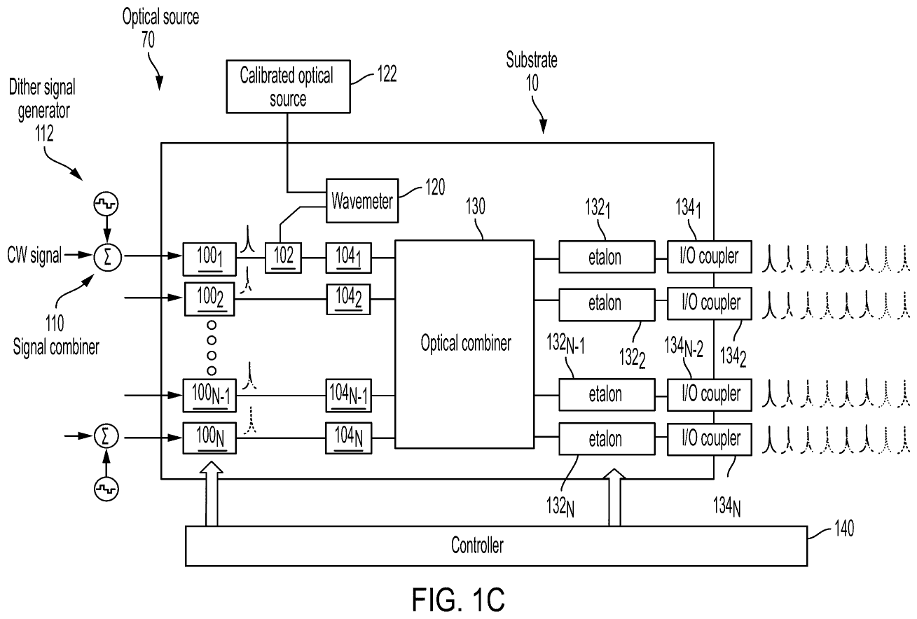

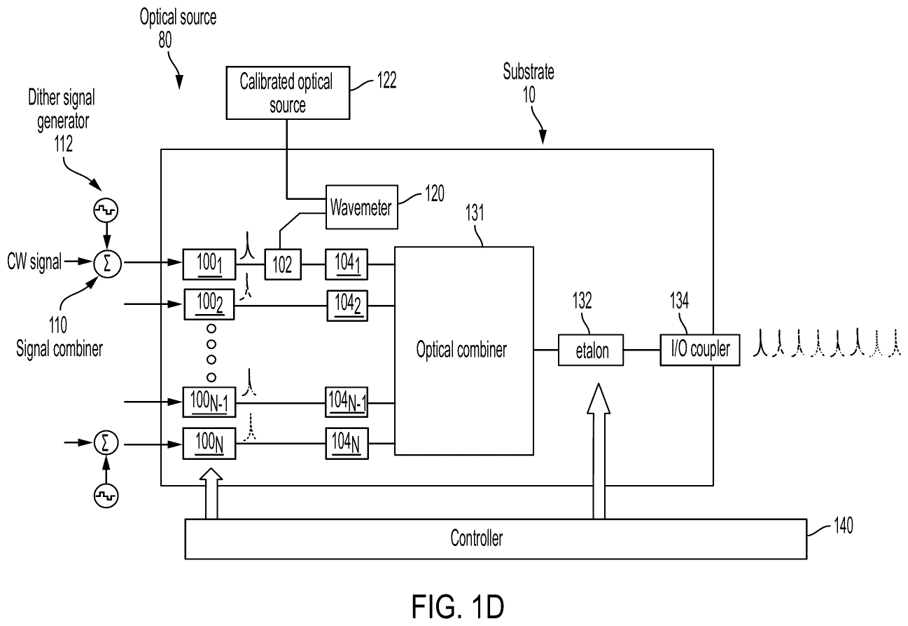

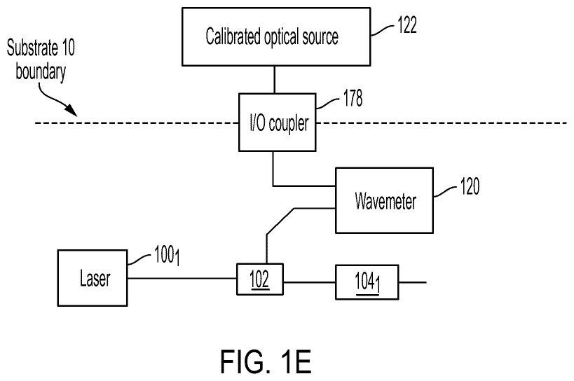

FIG. 1A is a block diagram illustrating an example of a tunable optical source 50 including an integrated wavemeter, in accordance with some embodiments. Tunable optical source 50 includes multiple tunable lasers 100₁, 100₂ . . . 100_{N-1}, 100_{N}. The tunable lasers define a tunable laser array. Each laser is configured to emit light at a different carrier wavelength, thereby supporting WDM schemes. The lasers are said to be tunable in that the carrier wavelength of each laser can be controlled electronically. A carrier wavelength may be the wavelength positioned in the middle of the wavelength range of emission of a laser. Alternatively or additionally, a carrier wavelength may be the wavelength that exhibits the absolute peak intensity within a wavelength range of emission. Alternatively or additionally, a carrier wavelength may be the nominal wavelength of emission of a laser. The wavelength of emission may be “nominal” in that the optical source may emit a finite spectrum of wavelengths around the nominal wavelength due to spectral broadening effects.

Laser tunability may be achieved using different mechanisms, including through current-based mechanisms and refractive index-based mechanisms. In some embodiments, the lasers may be implemented as distributed-feedback (DFB) lasers or distributed Bragg reflectors (DBR) lasers, though other types of lasers may be used. Each laser may be configured to emit a relatively high power level. High power levels enable use of the optical source in applications with stringent power budget requirements. For example, each laser may emit between 50 mW and 300 mW, between 100 mW and 300 mW, between 150 mW and 300 mW, between 200 mW and 300 mW, between 250 mW and 300 mW, between 50 mW and 250 mW, between 100 mW and 250 mW, between 150 mW and 250 mW, between 200 mW and 250 mW, between 50 mW and 200 mW, between 100 mW and 200 mW, between 150 mW and 200 mW, between 50 mW and 150 mW, between 50 mW and 100 mW or between any range within such ranges.

The lasers may be configured to emit in any suitable band, including in the O-band, in the S-band, in the C-band or in the L-band, for example. The nominal spectral spacing between adjacent carrier wavelengths may be set depending on the requirements of the system connected to the optical source. The spacing may be 100 GHz, 200 GHz, 400 GHz or any range between those values. The spectral spacing is said to be nominal in that it is subject to temperature fluctuations.

Controller 140 controls the operations of the tunable optical source. Controller 140 may be implemented using one or more processors, one or more applications-specific integrated circuits or any other suitable type of digital circuitry. Controller 140 may include analog-to-digital converters and digital-to-analog converters, which permit the controller to interface with components of the tunable optical source that are analog in nature while running control algorithms in the digital domain. Controller 140 may be mounted as part of a card on the same substrate hosting the lasers, or on a separate board.

In some embodiments, controller 140 controls the lasers so that, while the lasers do emit pulses of light at a particular repetition rate, their wavelengths of emission remain largely constant over time. To operate in this way, controller 140 drives the lasers with continuous wave (CW) signals. In other embodiments, controller 140 controls the lasers so that their wavelengths of emission slightly vary over time. To operate in this way, controller 140 drives the lasers with a combination of CW signals and dither signals. A signal combiner 110 combines a CW signal with the signal generated by a dither signal generator 112. A dither signal is a time-varying signal, whether in the form of a sinusoidal wave, square wave, triangular wave, sawtooth wave, a dithering code or even just noise, having an amplitude that is relatively small compared to the amplitude of the CW signal. The frequency of the dither signal is less than the repetition rate of the laser. For example, the dither signal may be in the kilohertz range or in the megahertz range. Driving a laser with a CW signal combined with a dither signal results in a small perturbation in the carrier wavelength emitted by the laser. This effect, referred to herein as wavelength dithering, may be used for a variety of reasons. For example, dithering can allow a receiver to uniquely identify a particular transmitter. Through dithering, an optical device can mark a signal with a unique signature, whether in the form of a particular dithering frequency or a particular dithering code. Device identification becomes particularly important in architectures having several devices placed in series along a waveguide bus. In some embodiments, detectors can rely on dithering frequencies or codes to identify which transmitter has transmitted certain data.

Optical source 50 further includes tap couplers 102₁, 102₂ . . . 102_{N-1}, 102_{N}. Each tap coupler routes a small fraction of the optical power generated by a corresponding laser (e.g., less than 10%, less than 5% or less than 1%) to a wavemeter 120. In the implementation of FIG. 1A, only one wavemeter is shown, but the source may include multiple wavemeters, each wavemeter being connected to a respective tap coupler.

Wavemeter 120 ensures that the wavelength of light emitted by a tunable laser is tightly locked to the target wavelength (a process referred to herein as laser calibration). A calibrated optical source 122 is used to calibrate a tunable laser. Calibrated optical source 122 is an external source configured to emit light, the carrier wavelength of which is known a priori. For example, the wavelength of emission of calibrated optical source 122 may be verified using an external optical spectrum analyzer or other instrumentation. In some embodiments, wavemeter 120 operates as follows. First, the carrier wavelength of calibrated optical source 122 is swept, and controller 140 maps the carrier wavelengths to the output of wavemeter 120. Then, controller 140 controls tunable laser 100₁ to emit light, causing wavemeter 120 to receive a fraction of the emitted light via tap coupler 102₁. By determining the response of the wavemeter to the laser light, controller 140 can infer the carrier wavelength of the laser light. This is done by mapping the response of the wavemeter to the laser light to the response of the wavemeter to the light emitted by the calibrated source. To the extent that the carrier wavelength differs from the target carrier wavelength, controller 140 can control the tunable laser to vary the carrier wavelength. This process can be repeated until controller 140 determines that the carrier wavelength of the tunable laser matches the target carrier wavelength. A similar process is repeated for the other tunable lasers of FIG. 1A. In some embodiments, the same calibrated optical source used to tune laser 100₁ may be further used to tune lasers 100₂ . . . 100_{N-1}, 100_{N}. In other embodiments, a dedicated calibrated optical source may be used for each laser.

Optical source 50 further includes optical amplifiers 104₁, 104₂ . . . 104_{N-1}, 104_{N}. Each amplifier is configured to amplify the power of the light emitted by a respective laser. The amplifiers may be implemented using semiconductor optical amplifiers (SOA), for example. The gain of the optical amplifiers may be between 5 dB and 30 dB, between 10 dB and 30 dB, between 15 dB and 30 dB, between 20 dB and 30 dB, between 25 dB and 30 dB, between 5 dB and 25 dB, between 10 dB and 25 dB, between 15 dB and 25 dB, between 20 dB and 25 dB, between 5 dB and 20 dB, between 10 dB and 20 dB, between 15 dB and 20 dB, between 5 dB and 15 dB, or between 5 dB and 10 dB, for example. Other ranges are also possible.

Optical combiner 130 has multiple inputs and multiple outputs. Each input receives light from a respective tunable laser. Therefore, each input of optical combiner 130 receives light at a different carrier wavelength. Optical combiner 130 is configured so that each output combines all the inputs that it receives. Thus, light that emerges from each output includes the entire wavelength comb generated by the tunable laser array. To operate in this way, optical combiner 130 may be wired to provide an optical all-to-all configuration. For example, each input of optical combiner 130 may be optically coupled to every output of optical combiner 130. In some embodiments, optical combiner 130 may lack active optical components (e.g., electrically controllable optical components) and the optical lanes connecting the inputs to the outputs may be hard wired. As such, optical combiner 130 may be viewed as a passive optical device.

Optical source 50 further includes etalons 132₁, 132₂ . . . 132_{N-1}, 132_{N}. Each etalon is coupled to a respective output of optical combiner 130. Each etalon can serve a dual purpose. First, an etalon suppresses ASE produced by the respective semiconductor optical amplifier while in the process of amplifying the incoming optical carrier. Second, an etalon ensures that the carrier wavelengths emitted by a tunable laser array are appropriately spaced with one another and comply with the desired WDM grid. Light is transmitted through the etalons only if the spectral content matches the spectral channels defined by the etalon. Light with wavelengths outside those channels is suppressed. Controller 140 can control the etalons to vary the wavelength passbands at which the etalons are transmissive. For example, each etalon may be thermally coupled to a heater. Causing the heater to vary the temperature of the etalon results in a redshift or blueshift in the spectral response. Possible implementations of the etalons are described in detail further below.

In the example of FIG. 1A, amplifiers 104₁, 104₂ . . . 104_{N-1}, 104_{N} are shows as being coupled between tap couplers 102₁, 102₂ . . . 102_{N-1}, 102_{N} and optical combiner 130. It should be noted, however, that the amplifiers may be positioned elsewhere along the optical paths from the lasers to the etalons. For example, amplifiers 104₁, 104₂ . . . 104_{N-1}, 104_{N} may be positioned between lasers 100₁, 100₂ . . . 100_{N-1}, 100_{N} and tap couplers 102₁, 102₂ . . . 102_{N-1}, 102_{N} or between the outputs of optical combiner 130 and etalons 132₁, 132₂ . . . 132_{N-1}, 132_{N}.

Optical source 50 further includes input/output (I/O) couplers 134₁, 134₂ . . . 134_{N-1}, 134_{N}. In some embodiments, each I/O coupler couples the output of an etalon to a respective optical fiber (not shown in FIG. 1A). Each fiber carries light having carrier wavelengths spanning the entire WDM grid. Therefore, each fiber can independently support WDM communication. The I/O couplers may be implemented as edge couplers or surface couplers, for example. In other embodiments, the T/O couplers permit coupling with other optical devices via free space optics.

In some embodiments, lasers 100₁, 100₂ . . . 100_{N-1}, 100_{N}, tap couplers 102₁, 102₂ . . . 102_{N-1}, 102_{N}, amplifiers 104₁, 104₂ . . . 104_{N-1}, 104_{N}, wavemeters 120, optical combiner 130, etalons 132₁, 132₂ . . . 132_{N-1}, 132_{N} and I/O couplers 134₁, 134₂ . . . 134_{N-1}, 134_{N} may be formed on the same semiconductor substrate 10, as shown in FIG. 1A. The semiconductor substrate may be made of a material suitable for generation and amplification of light via stimulated emission in the desired spectral range. For example, the semiconductor substrate may be made of InP or other suitable III-V materials. In other embodiments, tunable optical source 50 may be defined between two separate substrates. A first semiconductor substrate (having characteristics similar to the common substrate described above) may include lasers 100₁, 100₂ . . . 100_{N-1}, 100_{N}, tap couplers 102₁, 102₂ . . . 102_{N-1}, 102_{N}, amplifiers 104₁, 104₂ . . . 104_{N-1}, 104_{N} and wavemeters 120. Optical combiner 130, etalons 132₁, 132₂ . . . 132_{N-1}, 132_{N} and I/O couplers 134₁, 134₂ . . . 134_{N-1}, 134_{N} may be formed on another semiconductor substrate. This other semiconductor substrate may be made of a material having a thermo-optic coefficient that is less than that of the first semiconductor substrate. For example, the second semiconductor substrate may be a planar lightwave circuit (PLC); as such, optical combiner 130, etalons 132₁, 132₂ . . . 132_{N-1}, 132_{N} and I/O couplers 134₁, 134₂ . . . 134_{N-1}, 134_{N} may be made of silicon dioxide (with the core and cladding having slightly different doping levels to produce a refractive index contrast). In this way, the optical spectra of the optical combiner and the etalons may be less susceptible to temperature variations.

The implementation of an optical source 60, shown in FIG. 1B, is similar to the implementation of FIG. 1A (optical source 50) in that it also includes lasers 100₁, 100₂ . . . 100_{N-1}, 100_{N}, tap couplers 102₁, 102₂ . . . 102_{N-1}, 102_{N}, amplifiers 104₁, 104₂ . . . 104_{N-1}, 104_{N} and wavemeters 120. However, optical source 60 differs from optical source 50 in that it replaces optical combiner 130 with optical combiner 131. Optical combiner 130 includes multiple outputs whereas optical combiner 131 includes a single output. To operate in this way, optical combiner 131 may be wired to provide an optical all-to-1 configuration. For example, each input of optical combiner 131 may be optically coupled to the output of optical combiner 131. Similar to optical combiner 130, the optical lanes connecting the inputs to the output of optical combiner 131 may be hard wired. Etalon 132 and I/O coupler 134 operate in the same way as discussed above in connection with etalons 132₁, 132₂ . . . 132_{N-1}, 132_{N} and I/O couplers 134₁, 134₂ . . . 134_{N-1}, 134_{N}.

The implementation of an optical source 70, shown, in FIG. 1C, is similar to the implementation of FIG. 1A (optical source 50) in that it also includes lasers 100₁, 100₂ . . . 100_{N-1}, 100_{N}, amplifiers 104₁, 104₂ . . . 104_{N-1}, 10^{4N}, optical combiner 130, etalons 132₁, 132₂ . . . 132_{N-1}, 132_{N} and I/O couplers 134₁, 134₂ . . . 134_{N-1}, 134_{N}. However, optical source 70 differs from optical source 50 in that it only includes one tap coupler 102 and one wavemeter 120. In this implementation, instead of having to calibrate each laser using a wavemeter, the source calibrates one laser and then relies on the etalons to ensure that the other lasers emit light with the desired spectral spacing.

The implementation of an optical source 80, shown in FIG. 1D, is similar to the implementation of FIG. 1C (optical source 70) in that it also includes one tap coupler 102 and one wavemeter 120. As in optical source 60, optical source 80 replaces optical combiner 130 with optical combiner 131.

FIG. 1E is a block diagram illustrating a portion of a tunable optical source (e.g., optical source 50) in additional detail, in accordance with some embodiments. FIG. 1E illustrates that calibrated optical source 122 is placed outside substrate 10 while wavemeter 120 is disposed on substrate 10 with the tunable laser array. To permit optical coupling between calibrated optical source 122 and wavemeter 120, the substrate may further include an I/O coupler 178 in correspondence with the boundary of substrate 10. As described above in connection with I/O couplers 134, I/O coupler 178 may be a fiber coupler (edge coupler or surface coupler) or a free space optics coupler.

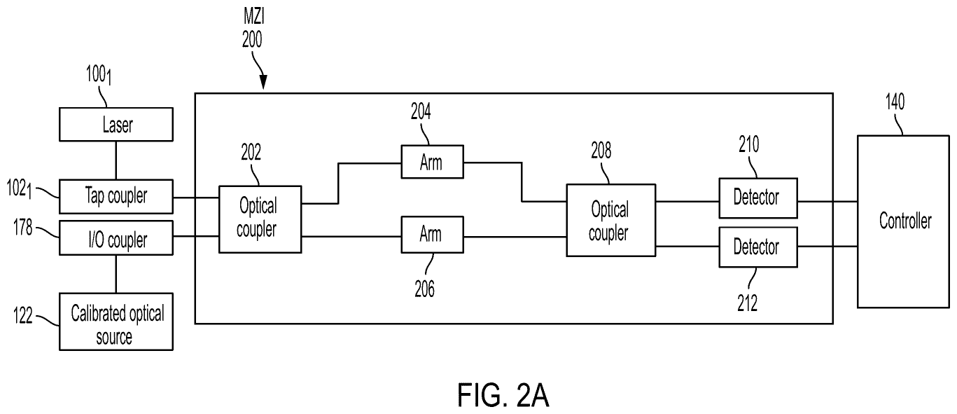

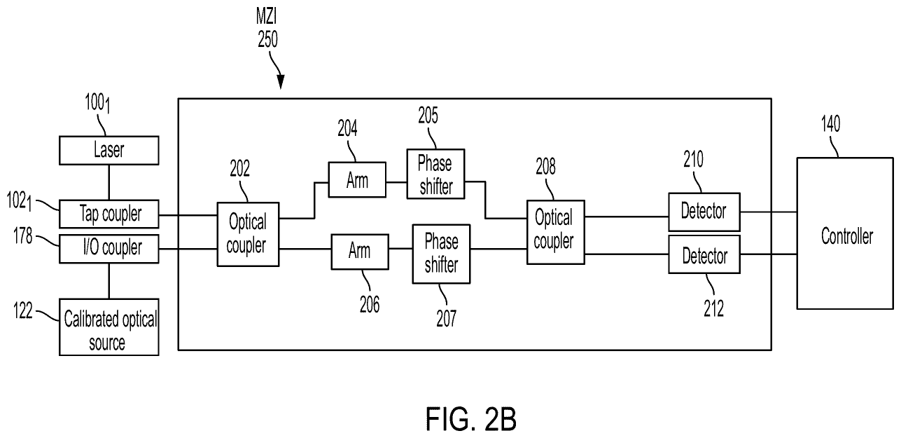

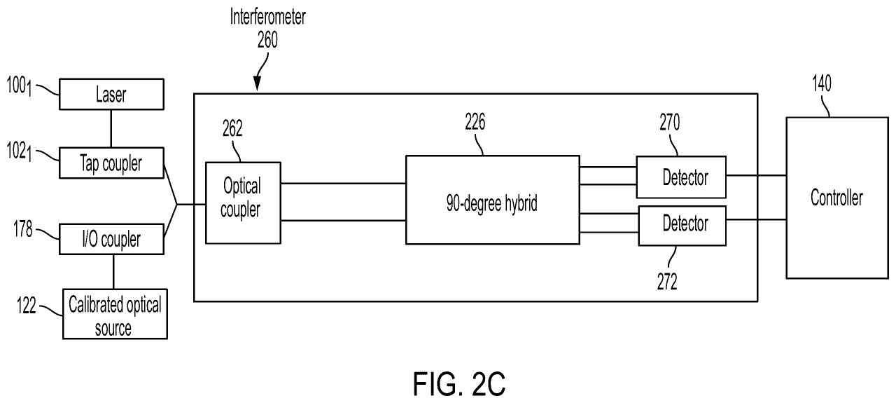

FIGS. 2A-2C are block diagrams illustrating examples of interferometers that may be used to implement wavemeter 120, in accordance with some embodiments. The implementations of FIGS. 2A-2B use Mach-Zehnder interferometers (MZI); the interferometer of FIG. 2A is a passive MZI while the interferometer of FIG. 2B is an active MZI. The interferometer of FIG. 2C, on the other hand, uses a 90-degree hybrid circuit.

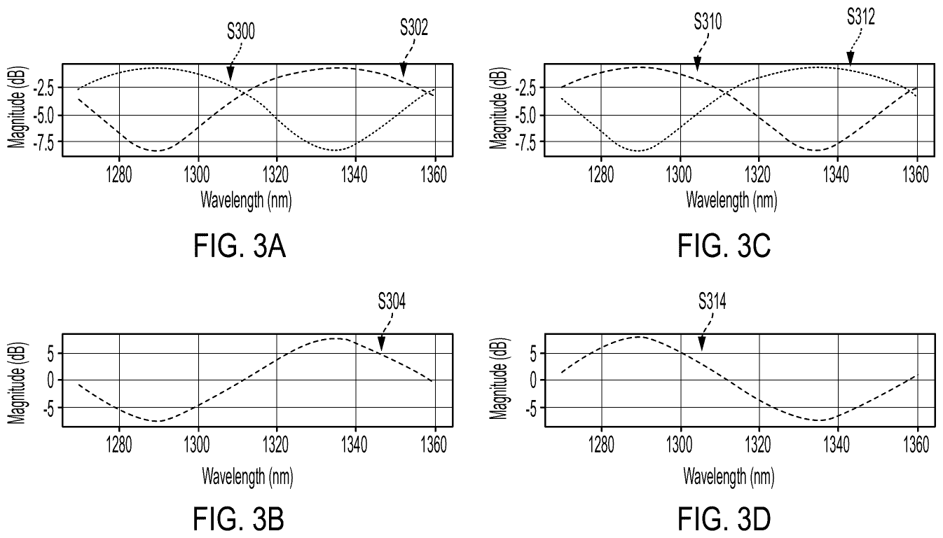

Referring first to FIG. 2A, MZI 200 is said to be passive in that it does not include electrically controllable optical components. Passive designs are desirable in some cases because they do not require electric energy to operate. MZI 200 has a first input coupled to calibrated optical source 122 via I/O coupler 178 and a second input coupled to laser 100₁ via tap coupler 102₁. Optical coupler 202, which may be implemented using a 50/50 directional coupler, couples the MZI's inputs to optical arms 204 and 206. Arms 204 and 206 have different optical lengths relative to each other, making the MZI an unbalanced MZL Optical coupler 208 couples arms 204 and 206 to the MZI's outputs. Optical coupler 208 may be implemented using an X/Y directional coupler, wherein X is between 55% and 95% and Y is between 5% and 45% (and X+Y equals 100%). As discussed in detail further below, designing MZI 200 to be unbalanced, in combination with optical coupler 208 being an X/Y directional coupler other than a 50/50 directional coupler, results in the MZI having a relatively low extinction ratio (e.g., less than 15 dB or less than 10 dB). Having a low extinction ratio is desirable in this instance because it results in a higher spectral resolution, as discussed below. The outputs of MZI 200 are coupled to detectors 210 and 212, respectively. The electrical signals generated by detectors 210 and 212 in response to receiving light from MZI 200 are supplied to controller 140. Controller 140, in turn, adjusts the carrier wavelength of laser 100₁ based on the signals generated by detectors 210 and 212. The operations of MZI 200 are described in connection with FIGS. 3A-3D.

Referring now to FIG. 2B, MZI 250 is said to be active in that it includes electrically controllable optical components-phase shifters 205 and 207. Active designs are desirable in some cases because, although they require some electric energy to operate, they can dynamically adjust the interferometer's response. This is because the effective optical path lengths of arms 204 and 206 can be varied by varying the phase difference introduced by phase shifters 205 and 207.

Interferometer 260, shown in FIG. 2C, differs from interferometers 200 and 250 in two respects. First, interferometer 260 is not implemented using an MZI; rather, it is implemented using a 90-degree optical hybrid 226. The 90-degree optical hybrid 226 receives two signals from optical coupler 262 and generates four output signals. These output signals have fixed relative phase shifts of 0°, 90°, 180°, and 270°. In this implementation, detectors 270 and 272 are implemented as balanced detectors. Second, interferometer 260 has a single input, to which both tap coupler 102₁ and I/O coupler 178 are connected.

The operations of wavemeter 120 can be appreciated from the plots of FIG. 3A-3D. These plots illustrate the spectral response of an MZI, such as MZI 200 or MZI 250. The operations of the implementation based on interferometer 260 are not illustrated, but interferometer 260 may operate similarly. FIG. 3A illustrates the magnitude of the electrical signal generated by detector 210 (curve S₃₀₀) and the magnitude of the electrical signal generated by detector 212 (curve S₃₀₂) upon reception of light generated by the calibrated optical source 122. Curves S₃₀₀ and S₃₀₂ are plotted as a function of the wavelength. In this plot, the wavelength axis represents the carrier wavelength of the light generated by the calibrated optical source 122. FIG. 3B is a plot illustrating the magnitude of the following curve:

$${S}_{304} = 10 x {log}_{10} ( {S}_{302} / {S}_{300} )$$

Signal S₃₀₄ represents the overall response of wavemeter 120 to light generated by calibrated optical source 122 when the carrier wavelength is swept from about 1290 nm to about 1365 nm. In some embodiments, controller 140 may store the response of wavemeter 120 to light generated by calibrated optical source 122 in a local memory, which may be used for future reference to calibrate the carrier wavelength of laser 100₁. For example, controller 140 may store a first vector containing values representing the frequencies of the light generated by calibrated optical source 122 and a second vector containing values representing the corresponding magnitudes.

FIG. 3C illustrates the magnitude of the electrical signal generated by detector 210 (curve S₃₁₀) and the magnitude of the electrical signal generated by detector 212 (curve S₃₂₂) upon reception of light generated by laser 100₁. In this plot, the wavelength axis represents the carrier wavelength of the light generated by laser 100₁. It should be noted that the response of FIG. 3C is phase shifted by π/2 relative to the response of FIG. 3A. This is because light generated by calibrated optical source 122 is supplied through the first input of the MZI while light generated by laser 100₁ is supplied through the second input of the MZI. FIG. 3D is a plot illustrating the magnitude of the following curve:

$${S}_{314} = 10 x {log}_{10} ( {S}_{312} / {S}_{310} )$$

Signal S₃₁₄ represents the response of wavemeter 120 to light generated by laser 100₁ as a function of wavelength. In some embodiments, calibration of laser 100₁ may be performed by assessing where the response of wavemeter 120 to light generated by laser 100₁ lands relative to the response of wavemeter 120 to light generated by calibrated optical source 122. This comparison may be performed by using the pre-stored response to light generated by calibrated optical source 122 as a look-up table, for example. Depending on the magnitude of the response to light generated by laser 100₁, controller 140 can infer the carrier wavelength of the laser light. If the carrier wavelength differs from the target wavelength, controller 140 can control laser 100₁ to vary the carrier wavelength. The process may be repeated until the carrier wavelength matches the target wavelength. In addition to calibrating the lasers using wavemeter 120, controller 140 may control the etalons to ensure that the carrier wavelengths are spaced in accordance with the desired WDM grid.

As can be appreciated from FIGS. 3B and 3D, the extinction ratio of wavemeter 120, in this example, is slightly less than 15 dB (the extinction ratio can be determined by taking the distance along the vertical axis between the maximum and the minimum of curves S₃₀₄ and S₃₁₄). Wavemeter 120 is designed to have a relatively small extinction ratio internationally. Having a small extinction ratio improves the controller's ability to resolve wavelengths along the horizontal axis, thus giving the controller a greater ability to accurately estimate the wavelength of the light emitted by a tunable laser.

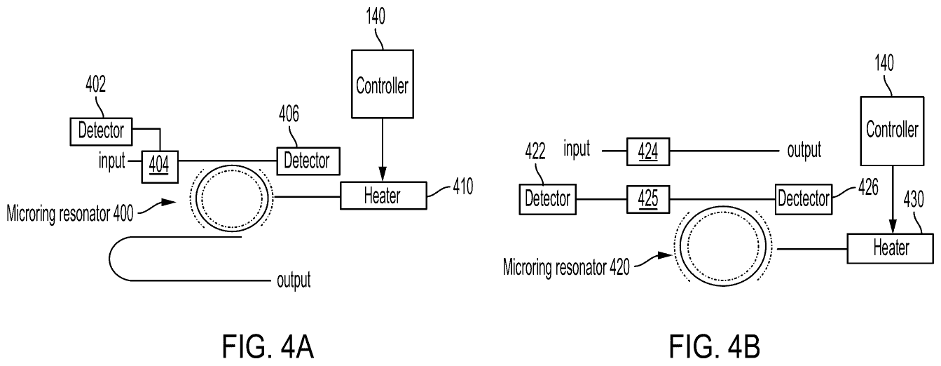

The etalons described herein may be implemented using any suitable device exhibiting a periodic spectral response. The spectral response is periodic in that it exhibits bands of relatively high transmission that are equally spaced from one another. The spacing is referred to as the free spectral range (FSR) of the etalon. Light having wavelengths within such bands is transmitted; light having wavelengths outside such bands is suppressed. To achieve this periodic response, the etalons may be implemented using an optical resonator, such as a microring resonator, a microdisk resonator, a racetrack resonator or a Fabry-Perot resonator, for example. Two examples of microring-based etalons are depicted in FIGS. 4A-4B, in accordance with some embodiments.

The etalon of FIG. 4A includes a microring resonator 400 evanescently coupled to a pair of waveguides. Light enters the etalon through the port labeled “input.” A tap coupler 404 steers a small fraction of the received optical power to detector 402. Detector 402 monitors the power associated with the incoming light before passing through the etalon. Another detector, detector 406, is positioned at the thru port of microring resonator 400 to monitor the amount of power that has not been coupled to microring resonator 400. In essence, detector 406 monitors the spectral misalignment between the incoming light and the resonant wavelength of the etalon. Light having wavelengths at or near the resonant wavelength couples to microring resonator 400 and exits the etalon through the port labelled “output.” A heater 410 is thermally coupled to microring resonator 400. By controlling the amount of heat generated by heater 410, controller 140 can control the temperature of microring resonator 400, and as a result the resonant wavelength (through the thermo-optic effect). Controller 140 may use the signals generated by detectors 402 and 406 to guide this process. For example, if the signal generated by detector 406 is approximately equal to the signal generated by detector 402, controller 140 may infer that the laser and the etalon's resonance are misaligned. By contrast, if the signal generated by detector 406 is negligible, controller 140 may infer that the laser and the etalon's resonance are properly aligned.

The etalon of FIG. 4B includes a microring resonator 420 evanescently coupled to a pair of waveguides. Light enters the etalon through the port labeled “input.” A tap coupler 424 steers a small fraction of the received optical power to coupler 425. A portion of the signal is supplied to detector 422 and a portion of the signal is supplied to detector 426, which is positioned at the thru port of microring resonator 420. Similar to FIG. 4A, detectors 422 and 426 monitor the fraction of the input power that has not been coupled with microring resonator 420. By controlling the amount of heat generated by heater 430, controller 140 can control the temperature of microring resonator 420, and as a result the resonant wavelength. Controller 140 may use the signals generated by detectors 422 and 426 to guide this process.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than described, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

What is claimed is:

1. An optical system, comprising:
a substrate;
a tunable laser array, formed on the substrate, comprising at least a first tunable laser; and
an optical wavemeter, formed on the substrate, having:
a first optical input coupled to the first tunable laser via a tap coupler;
a second optical input coupled to a first input/output (I/O) coupler;
a first optical output coupled to a first detector; and
a second optical output coupled to a second detector.

2. The optical system of claim 1, further comprising a calibrated optical source coupled to the second optical input of the optical wavemeter via the first I/O coupler.

3. The optical system of claim 1, wherein the optical wavemeter comprises an interferometer exhibiting an extinction ratio (ER) that is less than 15 dB.

4. The optical system of claim 1, wherein the optical wavemeter further comprises:
first and second optical arms coupling the first and second optical inputs to the first and second optical outputs; and
an optical coupler coupling the first and second optical arms to the first and second detectors.

5. The optical system of claim 4, wherein the first and second optical arms have different optical lengths.

6. The optical system of claim 4, wherein the optical coupler is an X/Y directional coupler, wherein X is between 55% and 95% and Y is between 5% and 45%.

7. The optical system of claim 1, further comprising:
an optical combiner, coupled to the tap coupler, configured to combine light received from the tunable lasers of the tunable laser array to a second I/O coupler.

8. The optical system of claim 7, further comprising:
an optical amplifier coupled to the optical combiner; and
an etalon coupled to the second I/O coupler, wherein the etalon exhibits a periodic spectral response.

9. The optical system of claim 8, wherein the etalon comprises an optical resonator and a heater thermally coupled to the optical resonator.

10. The optical system of claim 8, wherein the etalon exhibits a free spectral range that matches a spacing between adjacent carrier wavelengths of light emitted by the tunable laser array.

11. The optical system of claim 1, further comprising a dither signal generator configured to drive the first tunable laser.

12. A tunable optical source, comprising:
a substrate;
a tunable laser array, formed on the substrate, comprising at least a first tunable laser;
an optical wavemeter, formed on the substrate, having a first optical input coupled to the first tunable laser and a second optical input; and
a controller configured to calibrate the first tunable laser using a first signal generated by the optical wavemeter upon reception of light through the second optical input.

13. The tunable optical source of claim 12, wherein the optical wavemeter further comprises a first optical output coupled to a first detector and a second optical output coupled to a second detector, wherein the first and second detectors are configured to generate the first signal upon reception of light through the second optical input.

14. The tunable optical source of claim 13, wherein calibrating the first tunable laser using the first signal generated by the first and second detectors upon reception of light through the second optical input of the optical wavemeter comprises:
storing information indicative of the first signal generated by the first and second detectors in a memory;
obtaining a second signal generated by the first and second detectors upon reception of light through the first optical input of the optical wavemeter; and
mapping the second signal to the stored information indicative of the first signal.

15. The tunable optical source of claim 14, wherein storing information indicative of the first signal generated by the first and second detectors in the memory comprises:
storing a first vector indicative of carrier wavelengths of the light received through the second optical input of the optical wavemeter; and
storing a second vector indicative of magnitudes of the first signal for each carrier wavelength of the light received through the second optical input of the optical wavemeter.

16. The tunable optical source of claim 12, further comprising an etalon coupled to the first tunable laser, wherein the controller is further configured to, upon calibrating the first tunable laser, vary a spectral response associated with the etalon to match a carrier wavelength of light emitted by the first tunable laser.

17. The tunable optical source of claim 16, wherein varying the spectral response associated with the etalon comprises controlling a heater to vary a temperature of the etalon.

18. A method of operating a tunable optical source, the method comprising:
controlling a calibrated optical source to emit light;
obtaining a first signal generated by first and second detectors upon reception of the emitted light by an optical wavemeter that is disposed on a substrate; and
controlling a tunable laser, disposed on the substrate and coupled to the optical wavemeter, to emit light at a target carrier wavelength using the first signal generated by first and second detectors.

19. The method of claim 18, wherein controlling the first tunable laser to emit light at the target carrier wavelength using the first signal comprises:
storing information indicative of the first signal generated by the first and second detectors in a memory;
obtaining a second signal generated by the first and second detectors upon reception of light by the optical wavemeter; and
mapping the second signal to the stored information indicative of the first signal.

20. The method of claim 19, wherein storing information indicative of the first signal generated by the first and second detectors in the memory comprises:
storing a first vector indicative of carrier wavelengths of the light emitted by the calibrated optical source; and
storing a second vector indicative of magnitudes of the first signal for each carrier wavelength of the light emitted by the calibrated optical source.
